(19) United States
(12) Patent Application Publication
(10) Pub. No.: US 2013/0292634 A1
(43) Pub. Date: Nov. 7, 2013

(54) RESISTANCE-SWITCHING MEMORY CELLS HAVING REDUCED METAL MIGRATION AND LOW CURRENT OPERATION AND METHODS OF FORMING THE SAME

(71) Applicants: Yung-Tin Chen, Santa Clara, CA (US); Kun Hou, Milpitas, CA (US); Zhida Lan, San Jose, CA (US)

(72) Inventors: Yung-Tin Chen, Santa Clara, CA (US); Kun Hou, Milpitas, CA (US); Zhida Lan, San Jose, CA (US)

(21) Appl. No.: 13/465,263

(22) Filed: May 7, 2012

(51) Int. Cl. H01L 45/00; H01L 27/24

(52) U.S. Cl. 257/5; 257/2; 257/E27.004; 257/E45.003

(57) ABSTRACT

In some aspects, a memory cell is provided that includes a steering element, a metal-insulator-metal (“MIM”) stack coupled in series with the steering element, and a conductor above the MIM stack. The MIM stack includes a resistance switching element and a top electrode disposed on the resistance switching element, and the top electrode includes a highly doped semiconductor material. The memory cell does not include a metal layer between the MIM stack and the conductor. Numerous other aspects are provided.

### BACKGROUND

This invention relates to non-volatile memories, and more particularly to resistance-switching memory cells having reduced metal migration and low current operation and methods of forming the same.

Non-volatile resistance-switching memory cells are known. For example, Johnson et al. U.S. Pat. No. 6,034,882, which is incorporated by reference in its entirety for all purposes, describes a memory cell that includes a diode in series with a resistance-switching dielectric rupture antifuse. Some previously known diode-antifuse memory cells have experienced metal-migration-induced failures during set and reset operations.

It would be advantageous to reduce or eliminate metal migration in resistance-switching memory cells, such as antifuse memory cells. It also would be advantageous to reduce set and reset currents in resistance-switching memory cells.

### SUMMARY

In a first aspect of the invention, a memory cell is provided that includes a steering element, a metal-insulator-metal (“MIM”) stack coupled in series with the steering element, and a conductor above the MIM stack. The MIM stack includes a resistance switching element and a top electrode disposed on the resistance switching element, and the top electrode includes a highly doped semiconductor material. The memory cell does not include a metal layer between the MIM stack and the conductor.

In a second aspect of the invention, a monolithic three-dimensional memory array is provided that includes a first memory level monolithically formed above a substrate, and a second memory level monolithically formed above the first memory level. The first memory level includes a plurality of memory cells. Each memory cell includes a steering element, a MIM stack coupled in series with the steering element, and a conductor above the MIM stack. The MIM stack includes a resistance switching element and a top electrode disposed on the resistance switching element, and the top electrode includes a highly doped semiconductor material. The memory cell does not include a metal layer between the MIM stack and the conductor.

Other features and aspects of the present invention will become more fully apparent from the following detailed description, the appended claims and the accompanying drawings.

### BRIEF DESCRIPTION OF THE DRAWINGS

Features of the present invention can be more clearly understood from the following detailed description considered in conjunction with the following drawings, in which the same reference numerals denote the same elements throughout, and in which:

FIG. 1 is a diagram of an example memory cell in accordance with this invention;

FIG. 2A is a simplified perspective view of an example memory cell in accordance with this invention;

FIG. 2B is a simplified perspective view of another example memory cell in accordance with this invention;

FIG. 2C is a simplified perspective view of a portion of a first example memory level formed from a plurality of the memory cells of FIG. 2A;

FIG. 2D is a simplified perspective view of a portion of a first example three-dimensional memory array in accordance with this invention;

FIG. 2E is a simplified perspective view of a portion of a second example three-dimensional memory array in accordance with this invention;

FIG. 3A-3I are cross-sectional views of example memory cells in accordance with this invention;

FIGS. 4A-4E illustrate cross-sectional views of a portion of a substrate during an example fabrication of a single memory level in accordance with this invention; and

FIGS. 5A-5E illustrate cross-sectional views of a portion of a substrate during another example fabrication of a single memory level in accordance with this invention.

### DETAILED DESCRIPTION

A previously known memory cell includes a MIM stack coupled in series with a diode, with the MIM-stack and diode disposed between a first conductor (e.g., a bit line) and a second conductor (e.g., a word line). The MIM stack may include a resistance-switching element, such as one or more dielectric antifuse layers, sandwiched between a bottom electrode fabricated from highly doped semiconductor material, such as n+ silicon (“n+ Si”), and a top electrode fabricated from a conductive metal, such as titanium nitride (“TiN”). The diode may be a vertical polysilicon diode, such as a p-i-n diode that includes a lightly doped or an intrinsic polysilicon region disposed between a heavily doped p+ polysilicon region, and a heavily doped n+ polysilicon region.

The TiN top electrode of the MIM stack functions as a conductor and also promotes adhesion to the second electrode, which is typically fabricated from tungsten. In addition, a Ti/TiN layer may be disposed between the MIM stack and the diode to promote adhesion and serve as a crystallization template for the diode.

Although the Ti/TiN-containing layers may facilitate fabrication of such memory cells, it is believed that the Ti/TiN-containing layers may contribute to failure during use of the memory cells, such as during set and reset operations. In particular, without wanting to be bound by any particular theory, it is believed that memory cell failures may be the result of metal migration into the n+ Si bottom electrode from the Ti/TiN adhesion layer and/or the TiN top electrode. In addition, without wanting to be bound by any particular theory, it is believed that such Ti/TiN migration may occur during high-temperature endurance testing.

To reduce or eliminate such failures, devices and methods in accordance with this invention eliminate one or both Ti-containing layers. In one example embodiment in accordance with this invention, a memory cell is provided that includes a MIM stack having highly doped semiconductor top and bottom electrodes. Without wanting to be bound by any particular theory, it is believed that by using highly doped semiconductor material for the top electrode, such memory cells have reduced risk of TiN migration, and lower operating current compared to previously known memory cells that use a TiN top electrode.

In a second example embodiment in accordance with this invention, a memory cell is provided that includes a MIM stack that has a highly doped semiconductor top electrode, and that shares the highly doped top diode layer as the bottom electrode of the MIM. Without wanting to be bound by any particular theory, it is believed that by eliminating the Ti/TiN adhesion layer between the MIM stack and the diode, and by using highly doped semiconductor instead of TiN for the top electrode, such memory cells substantially eliminate the risk of TiN migration. In addition, such memory cells have even lower operating current compared to previously known Ti/TiN-containing memory cells.

In a third example embodiment in accordance with this invention, a three-dimensional array of memory cells is provided in which bit lines are vertically oriented, and are formed of a highly-doped semiconductor material. Multiple memory cells are stacked on top of one another, with each memory cell including a highly doped semiconductor electrode that is coupled to a corresponding word line. In addition, each memory cell includes one or more dielectric antifuse layers disposed between the highly doped semiconductor electrode and the vertically-oriented bit line. The three-dimensional array of memory cells does not include Ti/TiN-containing layers, such as adhesion layers. Without wanting to be bound by any particular theory, it is believed that by eliminating Ti/TiN adhesion layers, such three-dimensional arrays of memory cells substantially eliminate the risk of TiN migration.

### Example Inventive Memory Cell

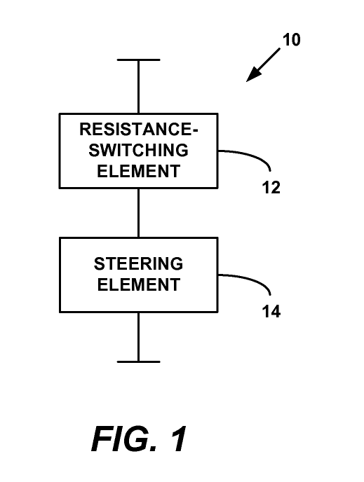

FIG. 1 is a diagram of an example memory cell 10 in accordance with this invention. Memory cell 10 includes a resistance-switching element 12 coupled to a steering element 14. Resistance-switching element 12 may be a one-time programmable resistance-switching element, or may be a reversible resistance-switching element. Resistance-switching element 12 may have two or more stable resistance levels, and thus may be used to store one or more bits of data. In some example embodiments, resistance-switching element 12 may include dielectric antifuse material, such as titanium oxide (“TiOₓ”), hafnium oxide (“HfOₓ”), tantalum oxide (“TaOₓ”), nickel oxide (“NiOₓ”), aluminum oxide (“AlOₓ”), zirconium oxide (“ZrOₓ”), and other similar dielectric antifuse materials.

In some example embodiments, resistance-switching element 12 may include a single layer of dielectric antifuse material (e.g., HfOₓ or other similar dielectric material), or more than one layer of dielectric antifuse material. For instance, in some embodiments, resistance-switching element 12 may be a multi-layer resistance-switching element that includes a first layer of dielectric antifuse material (e.g., HfOₓ or other similar dielectric material) and a second layer of antifuse material (e.g., TiOₓ or other similar dielectric material) disposed on the first layer of antifuse material. Persons of ordinary skill in the art will understand that multi-layer resistance-switching elements 12 may include more than two layers.

For simplicity, resistance-switching element 12 is referred to in the remaining description as “antifuse element 12.” Persons of ordinary skill in the art will understand that resistance-switching element 12 is not limited to antifuse materials, and may include other resistive-switching materials such as resistive-switching carbon materials, carbon nano-tubes, phase change resistive switching materials, dielectric/metal pair switching materials (e.g., HfOₓ/Hf), and other similar resistive-switching materials.

Steering element 14 may include a thin film transistor, a diode, a metal-insulator-metal tunneling current device, or another similar steering element that exhibits non-ohmic conduction by selectively limiting the voltage across and/or the current flow through antifuse element 12. In this manner, memory cell 10 may be used as part of a two- or three-dimensional memory array and data may be written to and/or read from memory cell 10 without affecting the state of other memory cells in the array.

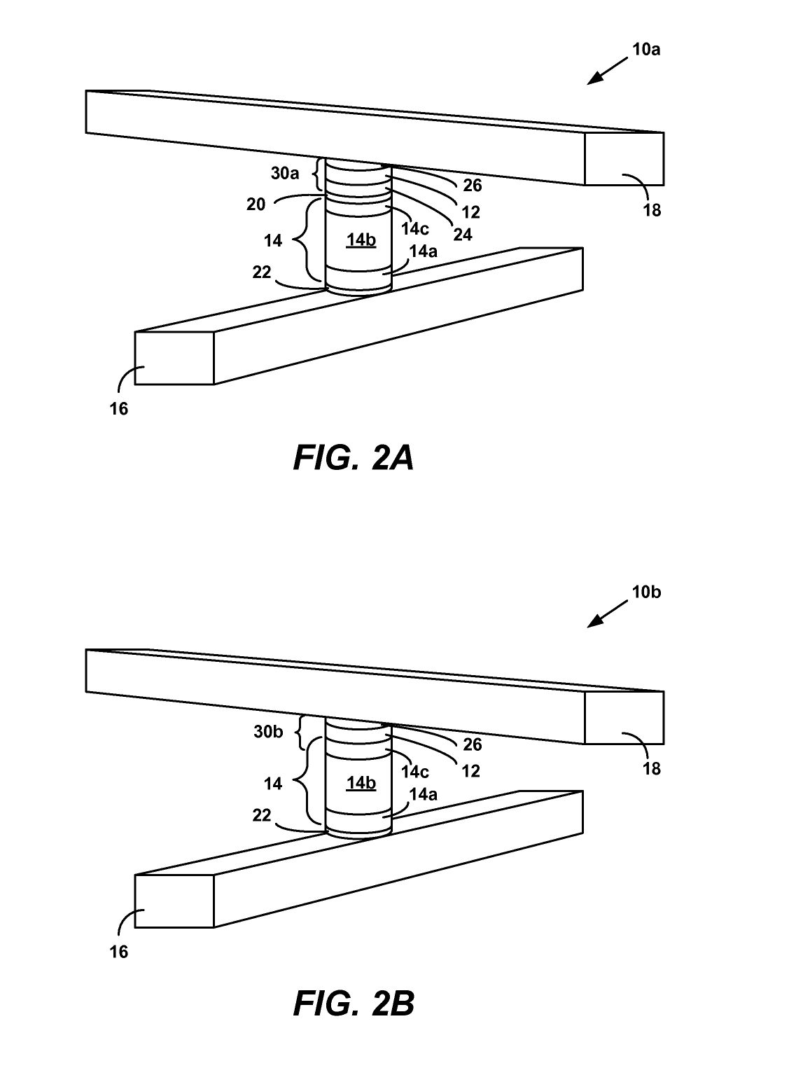

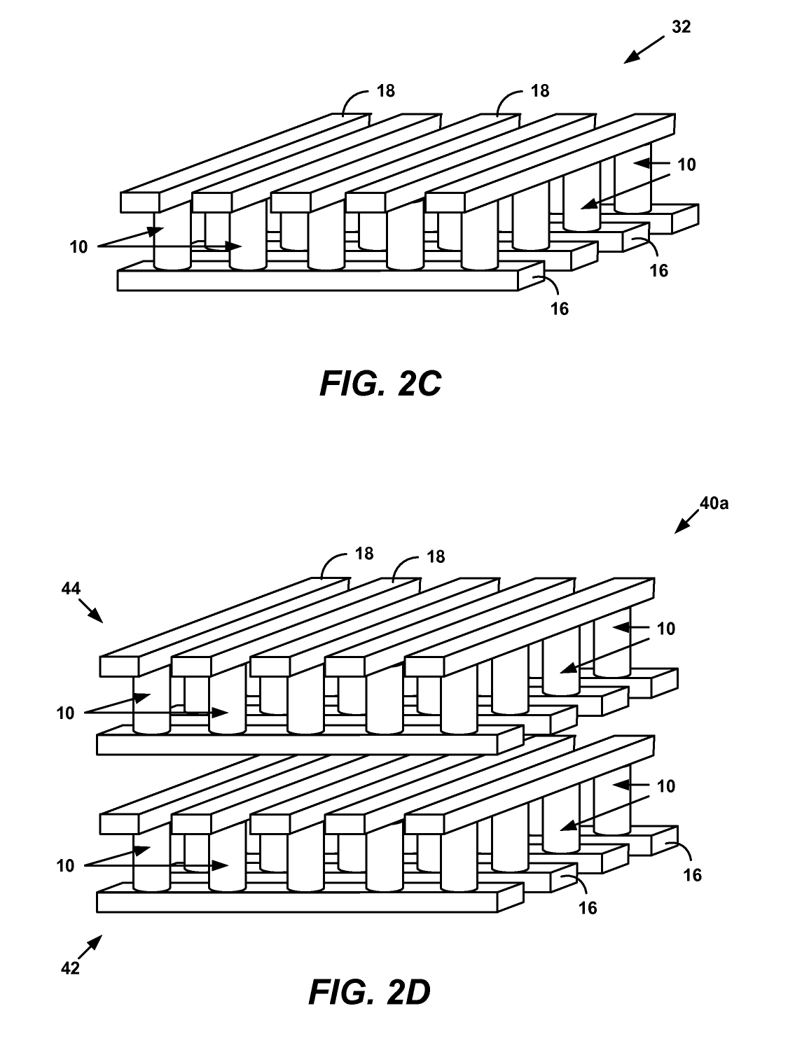

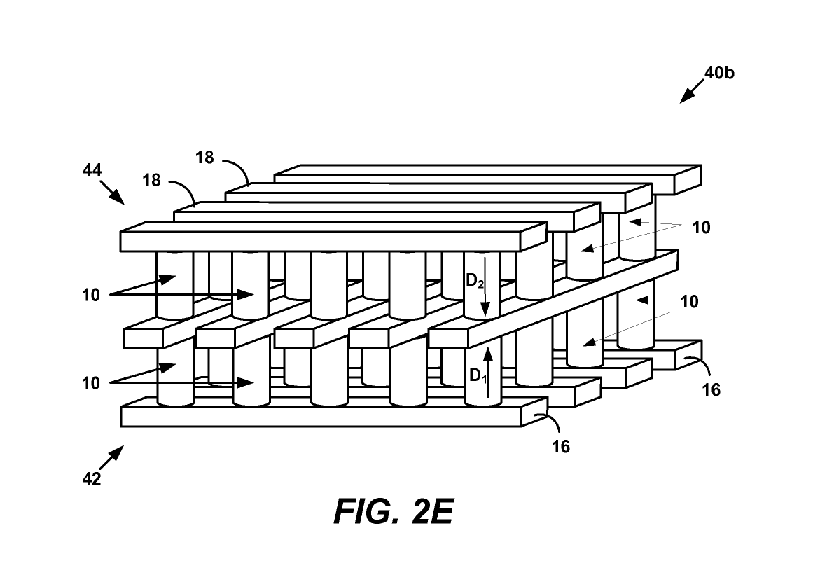

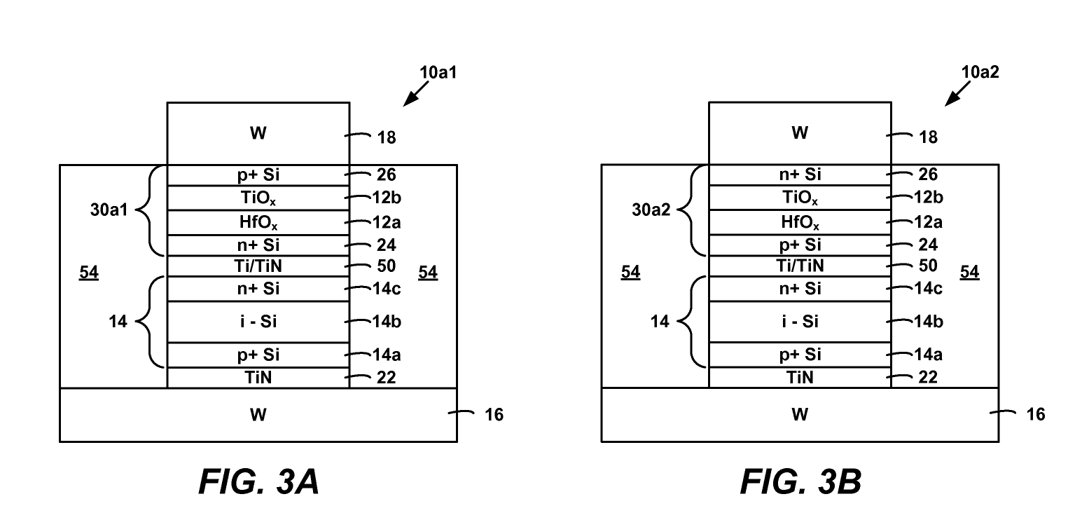

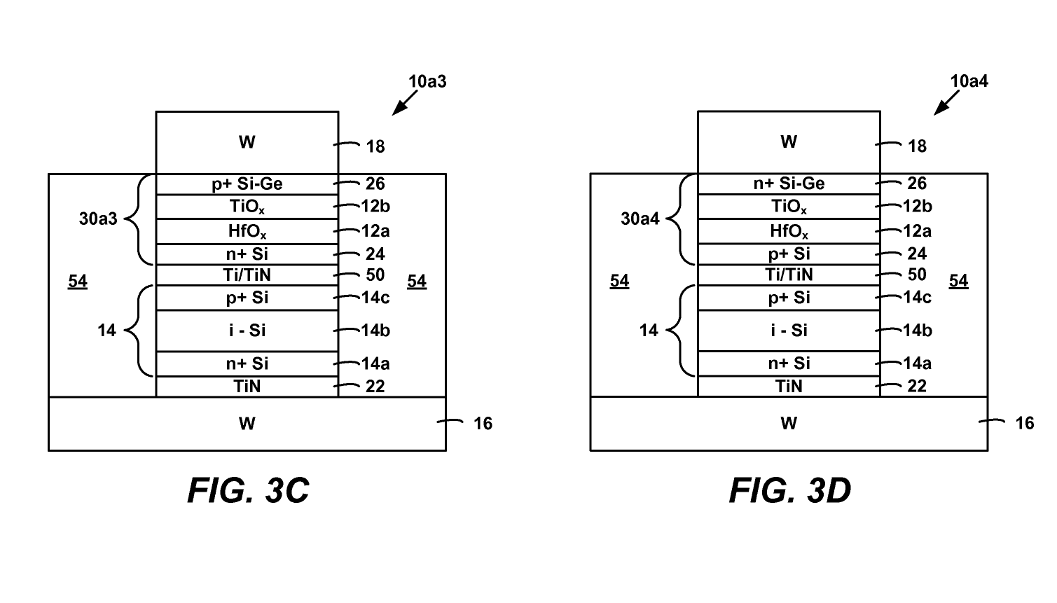

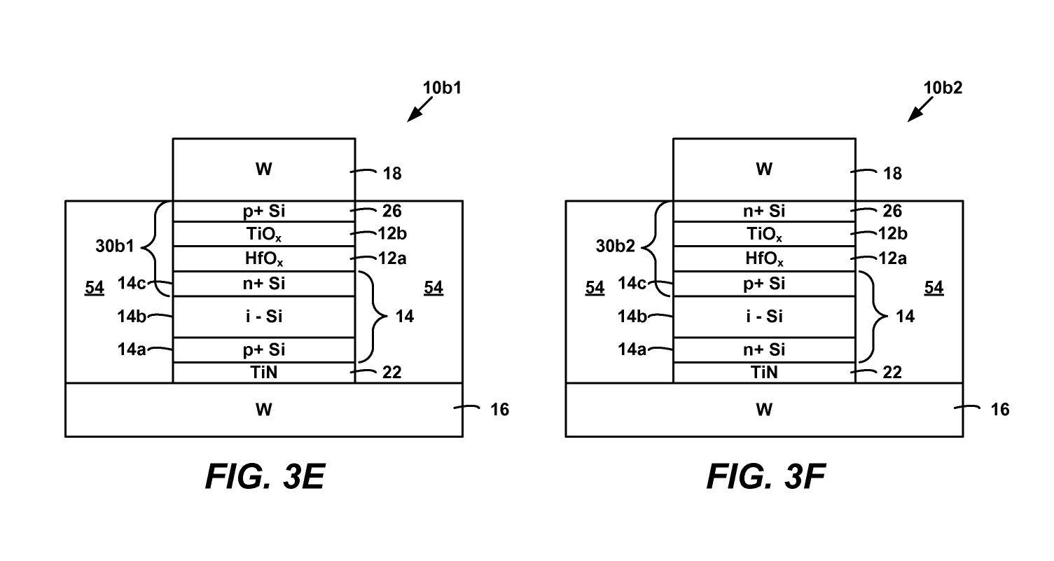

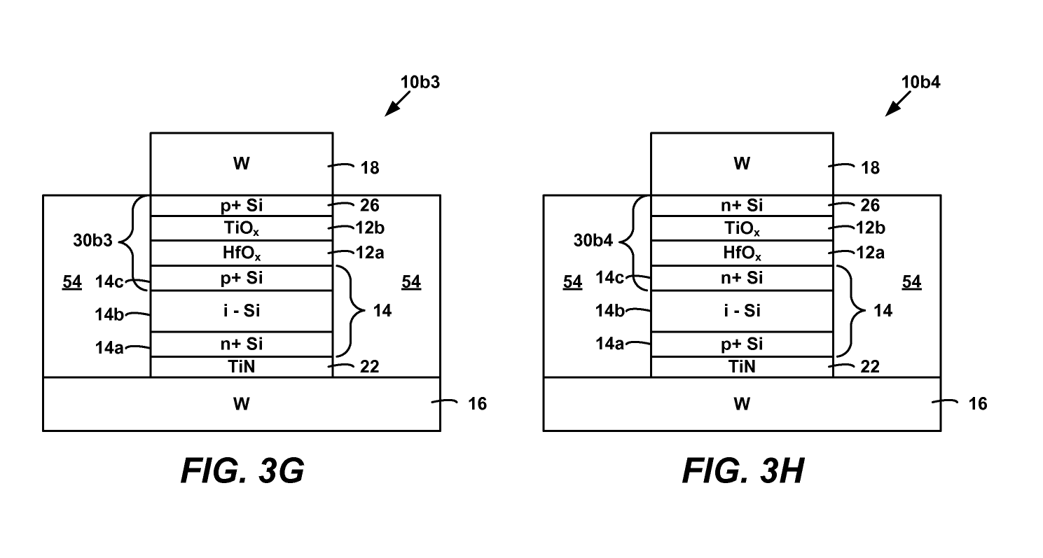

Example embodiments of memory cell 10, antifuse element 12 and steering element 14 are described below with reference to FIGS. 2A-2E and FIGS. 3A-3H.

### Example Embodiments of Memory Cells and Memory Arrays

FIG. 2A is a simplified perspective view of a first example memory cell 10a in accordance with this invention that includes steering element 14 and antifuse element 12. Antifuse element 12 is coupled in series with steering element 14 between a first conductor 16 and a second conductor 18.

In some embodiments, an adhesion layer 20 may be formed between antifuse element 12 and steering element 14, and an adhesion layer 22 may be formed between steering element 14 and first conductor 16. Adhesion layer 20 and adhesion layer 22 each may include Ti, TiN, tantalum, tantalum nitride (“TaN”), tungsten, tungsten nitride (“WN”), molybdenum or another similar material.

A first conducting layer 24 may be formed between antifuse element 12 and adhesion layer 20, and a second conducting layer 26 may be formed between antifuse element 12 and second conductor 18. First conducting layer 24 may be p+ silicon (“p+ Si”), p+ silicon-germanium (“p+ SiGe”), n+ silicon (“n+ Si”), n+ silicon-germanium (“n+ SiGe”), or other similar highly doped semiconductor material or combination of semiconductor materials. For example, first conducting layer 24 may be n+ Si having a doping concentration between about 1×10²⁰ cm⁻³ and about 1×10²² cm⁻³. Persons of ordinary skill in the art will understand that other doping types and doping concentrations may be used.

Likewise, second conducting layer 26 may be p+ Si, p+ SiGe, n+ Si, n+ SiGe, or other similar highly doped semiconductor material or combination of semiconductor materials. For example, second conducting layer 26 may be p+ Si having a doping concentration between about 1×10²⁰ cm⁻³ and about 1×10²² cm⁻³. Persons of ordinary skill in the art will understand that other doping types and doping concentrations may be used.

First conducting layer 24, antifuse element 12 and second conducting layer 26 may form a MIM stack 30a in series with steering element 14, with first conducting layer 24 forming a bottom electrode, and second conducting layer 26 forming a top electrode of MIM stack 30a. For simplicity, first conducting layer 24 and second conducting layer 26 will be referred to in the remaining discussion as “bottom electrode 24” and “top electrode 26,” respectively. In some embodiments, antifuse element 12 and/or MIM stack 30a may be positioned below steering element 14.

As discussed above, steering element 14 may include a thin film transistor, a diode, a metal-insulator-metal tunneling current device, or another similar steering element that exhibits non-ohmic conduction by selectively limiting the voltage across and/or the current flow through antifuse element 12. In the example of FIG. 2A, steering element 14 is a diode. Accordingly, steering element 14 is sometimes referred to herein as “diode 14.”

Diode 14 may include any suitable diode such as a vertical polycrystalline p-n or p-i-n diode, whether upward pointing with an n-region above a p-region of the diode or downward pointing with a p-region above an n-region of the diode. For example, diode 14 may include a heavily doped p+ polysilicon region 14a, a lightly doped or an intrinsic (unintentionally doped) polysilicon region 14b above the p+ polysilicon region 14a, and a heavily doped n+ polysilicon region 14c above intrinsic region 14b. It will be understood that the locations of the p+ and n+ regions may be reversed. Example embodiments of diode 14 are described below with reference to FIG. 3A.

First conductor 16 and/or second conductor 18 may include any suitable conductive material such as tungsten, any appropriate metal, heavily doped semiconductor material, a conductive silicide, a conductive silicide-germanide, a conductive germanide, or the like. In the embodiment of FIG. 2A, first and second conductors 16 and 18, respectively, are rail-shaped and extend in different directions (e.g., substantially perpendicular to one another). Other conductor shapes and/or configurations may be used. In some embodiments, barrier layers, adhesion layers, antireflection coatings and/or the like (not shown) may be used with the first conductor 16 and/or second conductor 18 to improve device performance and/or aid in device fabrication.

In contrast to previously known memory cells, example memory cell 10a does not includes a metal (e.g., TiN) top electrode 26. Without wanting to be bound by any particular theory, it is believed that memory cells in accordance with the first example embodiment of this invention, such as memory cell 10a, have a reduced risk of Ti/TiN migration compared to previously known memory cells that use a TiN top electrode. In addition, without wanting to be bound by any particular theory, it is believed that top electrode 26 may act as an in-situ current limiter, and therefore memory cell 10a may have a lower operating current compared to previously known memory cells that use a TiN top electrode.

To further reduce (and substantially eliminate) Ti/TiN migration, memory cells in accordance with this invention also may eliminate adhesion layer 20. In particular, FIG. 2B is a simplified perspective view of a second example memory cell 10b in accordance with this invention that includes steering element 14 and antifuse element 12. Memory cell 10b is similar to memory cell 10a of FIG. 2A, but does not include adhesion layer 20 or bottom electrode 24. In particular, memory cell 10b includes a MIM stack 30b that shares n+ polysilicon region 14c with diode 14. In this regard, n+ polysilicon region 14c functions not only as part of diode 14, but also as a bottom electrode of MIM stack 30b. As a result, bottom electrode 24 may be eliminated.

In contrast to previously known memory cells, example memory cell 10b does not include a TiN top electrode 26 or a Ti/TiN adhesion layer 30. Without wanting to be bound by any particular theory, it is believed that memory cells in accordance with the second example embodiment of this invention, such as memory cell 10b, have a substantially eliminated risk of Ti/TiN migration compared to previously known memory cells that use a TiN top electrode and a Ti/TiN adhesion layer between the diode and bottom electrode. As with example memory cell 10a, it is believed that in memory cell 10b, top electrode 26 may act as an in-situ current limiter, and therefore memory cell 10b may have a lower operating current compared to previously known memory cells that use a TiN top electrode.

FIG. 2C is a simplified perspective view of a portion of a first memory level 32 formed from a plurality of memory cells 10, such as memory cell 10a of FIG. 2A or memory cell 10b of FIG. 2B. For simplicity, MIM stack 30a (30b), diode 14, and adhesion layers 20 and 22 are not separately shown. Memory level 32 is a “cross-point” array including a plurality of bit lines (second conductors 18) and word lines (first conductors 16) to which multiple memory cells are coupled (as shown). Other memory array configurations may be used, as may multiple levels of memory.

For example, FIG. 2D is a simplified perspective view of a portion of a monolithic three dimensional array 40a that includes a first memory level 42 positioned below a second memory level 44. Memory levels 42 and 44 each include a plurality of memory cells 10 in a cross-point array. Persons of ordinary skill in the art will understand that additional layers (e.g., an interlevel dielectric) may be present between the first and second memory levels 42 and 44, but are not shown in FIG. 2D for simplicity. Other memory array configurations may be used, as may additional levels of memory. In the embodiment of FIG. 2D, all diodes may “point” in the same direction, such as upward or downward depending on whether p-i-n diodes having a p-doped region on the bottom or top of the diodes are employed, simplifying diode fabrication.

In some embodiments, the memory levels may be formed as described in U.S. Pat. No. 6,952,030, titled “High-Density Three-Dimensional Memory Cell” which is hereby incorporated by reference herein in its entirety for all purposes. For instance, the upper conductors of a first memory level may be used as the lower conductors of a second memory level that is positioned above the first memory level as shown in the alternative example three dimensional memory array 40b illustrated in FIG. 2E.

In such embodiments, the diodes on adjacent memory levels preferably point in opposite directions as described in U.S. patent application Ser. No. 11/692,151, filed Mar. 27, 2007, and titled “Large Array Of Upward Pointing P-I-N Diodes Having Large And Uniform Current” (hereinafter “the '151 application”), which is hereby incorporated by reference herein in its entirety for all purposes.

For example, as shown in FIG. 2E, the diodes of the first memory level 42 may be upward pointing diodes as indicated by arrow D1 (e.g., with p regions at the bottom of the diodes), whereas the diodes of the second memory level 44 may be downward pointing diodes as indicated by arrow D2 (e.g., with n regions at the bottom of the diodes), or vice versa.

A monolithic three dimensional memory array is one in which multiple memory levels are formed above a single substrate, such as a wafer, with no intervening substrates. The layers forming one memory level are deposited or grown directly over the layers of an existing level or levels. In contrast, stacked memories have been constructed by forming memory levels on separate substrates and adhering the memory levels atop each other, as in Leedy, U.S. Pat. No. 5,915,167, titled “Three Dimensional Structure Memory.” The substrates may be thinned or removed from the memory levels before bonding, but as the memory levels are initially formed over separate substrates, such memories are not true monolithic three dimensional memory arrays.

As described above, memory cells 10a and 10b in accordance with this invention include MIM stacks 30a and 30b that include top electrodes 26 that may be p+ Si, p+ SiGe, n+ Si, n+ SiGe, or other similar highly doped semiconductor material or combination of semiconductor materials. In addition, as described above, memory cells 10b in accordance with this invention include MIM stacks 30b that share a highly doped semiconductor layer with diode 14, with the highly doped semiconductor layer serving as both the bottom electrode of MIM stack 30b, and the top portion of diode 14. FIGS. 3A-3D illustrate cross-sectional views of various example embodiments of memory cell 10a of FIG. 2A, and FIGS. 3E-3H illustrate cross-sectional views of various example embodiments of memory cell 10b of FIG. 2B.

In particular, FIG. 3A shows an example memory cell 10a1 which includes first and second antifuse elements 12a and 12b, respectively, diode 14, first and second conductors 16 and 18, respectively, bottom electrode 24 and top electrode 26. Bottom electrode 24, first and second antifuse elements 12a and 12b and top electrode 26 form MIM stack 30a1. Memory cell 10a1 also may include adhesion layer 22, a silicide-forming metal layer 50, and dielectric material layer 54, as well as adhesion layers, antireflective coating layers and/or the like (not shown) which may be used with first and/or second conductors 16 and 18, respectively, to improve device performance and/or facilitate device fabrication. Persons of ordinary skill in the art will understand that memory cell 10a1 alternatively may include a single antifuse element, or more than two antifuse elements 12a and 12b.

Diode 14 may be a vertical p-n or p-i-n diode, which may either point upward or downward. In the embodiment of FIG. 2E in which adjacent memory levels share conductors, adjacent memory levels preferably have diodes that point in opposite directions such as downward-pointing p-i-n diodes for a first memory level and upward-pointing p-i-n diodes for an adjacent, second memory level (or vice versa).

In some embodiments, diode 14 may be formed from a polycrystalline semiconductor material such as polysilicon, a polycrystalline silicon-germanium alloy, polygermanium or any other suitable material. For example, diode 14 may include a heavily doped p+ polysilicon region 14a, a lightly doped or an intrinsic (unintentionally doped) polysilicon region 14b above the p+ polysilicon region 14a, and a heavily doped n+ polysilicon region 14c above intrinsic region 14b. It will be understood that the locations of the p+ and n+ regions may be reversed.

In some embodiments, a thin germanium and/or silicon-germanium alloy layer (not shown) may be formed on intrinsic region 14b to prevent and/or reduce dopant migration from n+ polysilicon region 14c into intrinsic region 14b. Use of such a layer is described, for example, in U.S. patent application Ser. No. 11/298,331, filed Dec. 9, 2005 and titled “Deposited Semiconductor Structure To Minimize N-Type Dopant Diffusion And Method Of Making” (hereinafter “the '331 application”), which is hereby incorporated by reference herein in its entirety for all purposes. In some embodiments, a few hundred angstroms or less of silicon-germanium alloy with about 10 at % or more of germanium may be employed.

Adhesion layer 22, such as titanium, TiN, tantalum, TaN, tungsten, WN, molybdenum, etc., may be formed between first conductor 16 and p+ region 14a (e.g., to prevent and/or reduce migration of metal atoms from first conductor 16 into the polysilicon regions). In FIG. 3A, adhesion layer 22 is shown as a TiN adhesion layer. Persons of ordinary skill in the art will understand that other adhesion layer materials may be used.

If diode 14 is fabricated from deposited silicon (e.g., amorphous or polycrystalline), a silicide layer may be formed on diode 14 to place the deposited silicon in a low resistivity state, as fabricated, such as described in Brad Herner et al., “Polysilicon Memory Switching: Electrothermal-Induced Order,” IEEE Trans. Electron. Devices, 53:9, pp. 2320-2327 (September 2006). Such a low resistivity state allows for easier programming of memory cell 10a1 as a large voltage is not required to switch the deposited silicon to a low resistivity state.

For example, a silicide-forming metal layer 50 such as titanium or cobalt may be deposited on n+ polysilicon region 14c. During a subsequent anneal step (described below), silicide-forming metal layer 50 and the deposited silicon of diode 14 interact to form silicide layer, consuming all or a portion of the silicide-forming metal layer 50. In some embodiments, a nitride layer (not shown) may be formed at a top surface of silicide-forming metal layer 50.

For example, if silicide-forming metal layer 50 is Ti, a TiN layer may be formed at a top surface of silicide-forming metal layer 50. In FIG. 3A, silicide-forming metal layer 50 is shown as a Ti/TiN silicide-forming metal layer. Persons of ordinary skill in the art will understand that other silicide-forming metal layer materials may be used.

A rapid thermal anneal (“RTA”) step may then be performed to form silicide regions by reaction of silicide-forming metal layer 50 with n+ region 14c. The RTA may be performed at about 600° C. to about 750° C. for about 1 minute, and causes silicide-forming metal layer 50 and the deposited silicon of diode 14 to interact to form a silicide layer, consuming all or a portion of silicide-forming metal layer 50. An additional, higher temperature anneal (e.g., such as at about 750° C. as described below) may be used to crystallize the diode.

As described in U.S. Pat. No. 7,176,064, titled “Memory Cell Comprising A Semiconductor Junction Diode Crystallized Adjacent To A Silicide,” which is hereby incorporated by reference herein in its entirety for all purposes, silicide-forming materials such as titanium and/or cobalt react with deposited silicon during annealing to form a silicide layer. The lattice spacings of titanium silicide and cobalt silicide are close to that of silicon, and it appears that such silicide layers may serve as “crystallization templates” or “seeds” for adjacent deposited silicon as the deposited silicon crystallizes (e.g., the silicide layer enhances the crystalline structure of diode 14 during annealing). Lower resistivity silicon thereby is provided. Similar results may be achieved for silicon-germanium alloy and/or germanium diodes.

In embodiments in which a nitride layer was formed at a top surface of silicide-forming metal layer 50, following the RTA step, the nitride layer may be stripped using a wet chemistry. For example, if silicide-forming metal layer 50 includes a TiN top layer, a wet chemistry (e.g., ammonium, peroxide, water in a 1:1:1 ratio) may be used to strip any residual TiN. In some embodiments, the nitride layer formed at a top surface of silicide-forming metal layer 50 may remain, or may not be used at all.

Bottom electrode 24 is formed above silicide-forming metal layer 50, and is formed of highly doped semiconductor material. Without wanting to be bound by any particular theory, it is believed that bottom electrode 24 may act as in-situ current limiter, and may limit current through MIM stack 30a1 during programming.

In the embodiment of FIG. 3A, bottom electrode 24 is n+ Si having a doping concentration between about 1×10²⁰ cm⁻³ and about 1×10²² cm⁻³. Persons of ordinary skill in the art will understand that other doping types and doping concentrations may be used.

In some embodiments, n+ Si bottom electrode 24 may have a thickness between about 20 angstroms and about 150 angstroms, more generally between about 10 angstroms and about 250 angstroms, although other thicknesses may be used. n+ Si bottom electrode 24 may be formed by chemical vapor deposition (“CVD”), low pressure CVD (“LPCVD”), plasma-enhanced CVD (“PECVD”), sputter deposition, laser ablation deposition, epitaxy growth deposition, or other similar processes.

Table 1, below, provides example LPCVD process parameters for forming n+ Si bottom electrode 24:

TABLE 1
EXAMPLE n+ Si
LPCVD DEPOSITION PARAMETERS

| PROCESS PARAMETER | BROAD RANGE | NARROW RANGE |
|---|---|---|
| Temperature (C.) | 480-620 | 500-580 |
| Pressure (mTorr) | 100-700 | 300-500 |
| SiH₄ flow rate (sccm) | 100-400 | 200-300 |
| PH₃ flow rate (sccm) | 10-50 | 20-40 |
| Carrier gas flow rate (sccm) | 150-250 | 180-220 |

First and second antifuse elements 12a and 12b are formed above n+ Si bottom electrode 24. In some embodiments, first antifuse element layer 12a may have a thickness between about 25 angstroms and about 45 angstroms, more generally between about 20 angstroms and about 50 angstroms, although other thicknesses may be used. In some embodiments, second antifuse element layer 12b may have a thickness between about 5 angstroms and about 15 angstroms, more generally between about 2 angstroms and about 20 angstroms, although other thicknesses may be used.

For example, first antifuse element layer 12a may be HfOₓ, ZrOₓ, LaₓO_{y}, TaₓO_{y}, SrTiOₓ, or other similar dielectric material, second antifuse element layer 12b may be TiOₓ, SiO₂, Al₂O₃, Si₃N₄, or other similar dielectric material. Other similar dielectric materials may be used.

First and second antifuse elements 12a and 12b may be formed over n+ Si bottom electrode 24 using any suitable formation process, such as atomic layer deposition (“ALD”), physical vapor deposition (“PVD”), rapid thermal oxidation (“RTO”), high density plasma CVD (“HDP-CVD”), CVD, slot plan antenna plasma technology (“SPA”), or other similar processes. Persons of ordinary skill in the art will understand that other processes may be used to form first and second antifuse elements 12a and 12b. For low current operation and good data retention, first and second antifuse elements 12a and 12b preferably are each formed as an amorphous structure.

Top electrode 26 is formed above first and second antifuse elements 12a and 12b, and is formed of highly doped semiconductor material. Without wanting to be bound by any particular theory, it is believed that top electrode 26 may act as in-situ current limiter, and may limit current through MIM stack 30a1 during programming.

In the embodiment of FIG. 3A, top electrode 26 is p+ Si having a doping concentration between about 1×10²⁰ cm⁻³ and about 1×10²² cm⁻³. Persons of ordinary skill in the art will understand that other doping types and doping concentrations may be used.

In some embodiments, p+ Si top electrode 26 may have a thickness between about 20 angstroms and about 150 angstroms, more generally between about 10 angstroms and about 250 angstroms, although other thicknesses may be used. p+ Si top electrode 26 may be formed by CVD, LPCVD, PECVD, sputter deposition, laser ablation deposition, epitaxy growth deposition, or other similar processes.

Table 2, below, provides example LPCVD process parameters for forming p+ Si top electrode 26:

TABLE 2
EXAMPLE p+ Si
LPCVD DEPOSITION PARAMETERS

| PROCESS PARAMETER | BROAD RANGE | NARROW RANGE |
|---|---|---|
| Temperature (C.) | 480-620 | 500-580 |
| Pressure (mTorr) | 100-700 | 300-500 |
| SiH₄ flow rate (sccm) | 100-400 | 200-300 |
| BCL₃ flow rate (sccm) | 20-60 | 30-50 |
| Carrier gas flow rate (sccm) | 200-500 | 300-400 |

Referring again to FIG. 3A, second conductor 18 is formed above MIM stack 30a1. Second conductors 18 may be formed from any suitable conductive material such as tungsten, another suitable metal, a conductive silicide, a conductive silicide-germanide, a conductive germanide, or the like deposited by PVD or any other any suitable method (e.g., CVD, etc.). Other conductive layer materials may be used.

In example embodiments of this invention, such as depicted in FIG. 3A, second conductor 18 is tungsten. To form a tungsten second conductor 18 on a highly doped silicon top electrode 26, the following example processing techniques may be used. First, p+ Si top electrode 26 may be cleaned using a dilute hydrofluoric/sulfuric acid clean. Such cleaning may be performed in any suitable cleaning tool, such as a Raider tool, available from Semitool of Kalispell, Mont. Example post-etch cleaning may include using ultra-dilute sulfuric acid (e.g., about 1.5-1.8 wt %) for about 60 seconds and/or ultra-dilute hydrofluoric (“HF”) acid (e.g., about 0.4-0.6 wt %) for 60 seconds. Megasonics may or may not be used. Other clean chemistries, times and/or techniques may be employed.

In addition, during tungsten deposition, an argon gas pre-sputtering clean step may be used to in-situ clean the surface of p+ Si top electrode 26 to remove any native oxide.

Further, a thin adhesions layer, such a tungsten nitride layer may be formed on p+ Si top electrode 26 to improve adhesion between tungsten second conductor 18 and highly doped silicon top electrode 26. For example, a tungsten nitride layer between about 50 angstroms and about 150 angstroms may be deposited on top electrode 26. Other adhesion layer materials and thicknesses may be used.

The deposited conductive layer may be patterned and etched to form second conductors 18. In at least one embodiment, second conductors 18 are substantially parallel, substantially coplanar conductors that extend in a different direction than first conductors 16.

Referring now to FIG. 3B, an alternative example memory cell 10a2 is described. Example memory cell 10a2 is similar to example memory cell 10a1 of FIG. 3A, except that memory cell 10a2 includes a MIM stack 30a2, with p+ Si bottom electrode 24, and n+ Si top electrode 26.

p+ Si bottom electrode 24 may have a doping concentration between about 1×10²⁰ cm⁻³ and about 1×10²² cm⁻³, a thickness between about 20 angstroms and about 150 angstroms, more generally between about 10 angstroms and about 250 angstroms, and may be formed by CVD, LPCVD, PECVD, sputter deposition, laser ablation deposition, epitaxy growth deposition, or other similar processes. Persons of ordinary skill in the art will understand that other doping types and doping concentrations, thicknesses, and processing techniques may be used. p+ Si bottom electrode 24 may be formed using the example processing parameters of Table 2, above.

n+ Si top electrode 26 may have a doping concentration between about 1×10²⁰ cm⁻³ and about 1×10²² cm⁻³, a thickness between about 20 angstroms and about 150 angstroms, more generally between about 10 angstroms and about 250 angstroms, and may be formed by CVD, LPCVD, PECVD, sputter deposition, laser ablation deposition, epitaxy growth deposition, or other similar processes. Persons of ordinary skill in the art will understand that other doping types and doping concentrations, thicknesses, and processing techniques may be used. n+ Si top electrode 26 may be formed using the example processing parameters of Table 1, above.

FIG. 3C shows an example memory cell 10a3 which is similar to example memory cell 10a1 of FIG. 3A, except that diode 14 is inverted, with n+ Si layer 14a on the bottom of diode 14, and p+ Si layer 14c on the top of diode 14, and memory cell 10a3 includes a MIM stack 30a3, with n+ Si bottom electrode 24, and p+ Si—Ge top electrode 26.

n+ Si bottom electrode 24 may have a doping concentration between about 1×10²⁰ cm⁻³ and about 1×10²² cm⁷³, a thickness between about 20 angstroms and about 150 angstroms, more generally between about 10 angstroms and about 250 angstroms, and may be formed by CVD, LPCVD, PECVD, sputter deposition, laser ablation deposition, epitaxy growth deposition, or other similar processes. Persons of ordinary skill in the art will understand that other doping types and doping concentrations, thicknesses, and processing techniques may be used. n+ Si bottom electrode 24 may be formed using the example processing parameters of Table 1, above.

p+ Si—Ge top electrode 26 may have a doping concentration between about 1×10²⁰ cm⁻³ and about 1×10²² cm⁻³. Persons of ordinary skill in the art will understand that other doping types and doping concentrations may be used. In some embodiments, p+ Si—Ge top electrode 26 may have a thickness between about 20 angstroms and about 150 angstroms, more generally between about 10 angstroms and about 250 angstroms, although other thicknesses may be used. p+ Si—Ge top electrode 26 may be formed by CVD, LPCVD, PECVD, sputter deposition, laser ablation deposition, epitaxy growth deposition, or other similar processes.

Table 3, below, provides example LPCVD process parameters for forming p+ Si—Ge top electrode 26:

TABLE 3
EXAMPLE p+ Si—Ge
LPCVD DEPOSITION PARAMETERS

| PROCESS PARAMETER | BROAD RANGE | NARROW RANGE |
|---|---|---|
| Temperature (C.) | 400-560 | 450-510 |
| Pressure (mTorr) | 500-1100 | 700-900 |
| SiH₄ flow rate (sccm) | 100-400 | 200-300 |
| BCL₃ flow rate (sccm) | 40-100 | 60-80 |
| GeH₄ flow rate (sccm) | 5-15 | 7-13 |
| Carrier gas flow rate (sccm) | 200-500 | 300-400 |

FIG. 3D shows an example memory cell 10a4 which is similar to example memory cell 10a2 of FIG. 3B, except that diode 14 is inverted, with n+ Si layer 14a on the bottom of diode 14, and p+ Si layer 14c on the top of diode 14, and memory cell 10a4 includes a MIM stack 30a4, with p+ Si bottom electrode 24, and n+ Si—Ge top electrode 26.

p+ Si bottom electrode 24 may have a doping concentration between about 1×10²⁰ cm⁻³ and about 1×10²² cm⁻³, a thickness between about 20 angstroms and about 150 angstroms, more generally between about 10 angstroms and about 250 angstroms, and may be formed by CVD, LPCVD, PECVD, sputter deposition, laser ablation deposition, epitaxy growth deposition, or other similar processes. Persons of ordinary skill in the art will understand that other doping types and doping concentrations, thicknesses, and processing techniques may be used. p+ Si bottom electrode 24 may be formed using the example processing parameters of Table 2, above.

n+ Si—Ge top electrode 26 may have a doping concentration between about 1×10²⁰ cm⁻³ and about 1×10²² cm⁻³. Persons of ordinary skill in the art will understand that other doping types and doping concentrations may be used.

In some embodiments, n+ Si—Ge top electrode 26 may have a thickness between about 20 angstroms and about 150 angstroms, more generally between about 10 angstroms and about 250 angstroms, although other thicknesses may be used. n+ Si—Ge top electrode 26 may be formed by CVD, LPCVD, PECVD, sputter deposition, laser ablation deposition, epitaxy growth deposition, or other similar processes.

Table 4, below, provides example LPCVD process parameters for forming n+ Si—Ge top electrode 26:

TABLE 4
EXAMPLE n+ Si—Ge
LPCVD DEPOSITION PARAMETERS

| PROCESS PARAMETER | BROAD RANGE | NARROW RANGE |
|---|---|---|
| Temperature (C.) | 400-560 | 450-510 |
| Pressure (mTorr) | 500-1100 | 700-900 |
| SiH₄ flow rate (sccm) | 100-400 | 200-300 |
| PH₃ flow rate (sccm) | 20-70 | 35-55 |
| GeH₄ flow rate (sccm) | 5-15 | 7-13 |
| Carrier gas flow rate (sccm) | 100-300 | 160-240 |

Referring now to FIG. 3E, an example memory cell 10b1 is described which includes first and second antifuse elements 12a and 12b, respectively, diode 14, and first and second conductors 16 and 18, respectively, and top electrode 26. Memory cell 10b1 includes a MIM stack 30b1 that shares n+ polysilicon region 14c with diode 14. In this regard, n+ polysilicon region 14c functions not only as part of diode 14, but also as a bottom electrode of MIM stack 30b1.

Memory cell 10b1 also may include adhesion layer 22 and dielectric material layer 54, as well as adhesion layers, antireflective coating layers and/or the like (not shown) which may be used with first and/or second conductors 16 and 18, respectively, to improve device performance and/or facilitate device fabrication.

As in memory cells 10a1-10a4, a silicide layer may be formed on diode 14 to place the deposited silicon in a low resistivity state, as fabricated, as described above. For example, as described above, a silicide-forming metal layer such as titanium or cobalt may be deposited on n+ polysilicon region 14c, a nitride layer may be formed at a top surface of silicide-forming metal layer, and an RTA step may be used to form a silicide layer.

Unlike the embodiments shown in FIGS. 3A-3D, however, following the RTA step, the nitride layer and any remaining silicide-forming metal layer are removed. For example, if silicide-forming metal layer is a Ti/TiN layer, a wet chemistry (e.g., ammonium, peroxide, water in a 1:1:1 ratio) may be used to strip the residual Ti/TiN, leaving n+ polysilicon region 14c exposed. A chemical mechanical polishing (“CMP”) step may be desired to smooth out the surface of n+ poly-silicon region 14c after wet chemical removal of nitride layer.

Following the Ti/TiN strip step, first and second antifuse elements 12a and 12b are formed above n+ polysilicon region 14c. In some embodiments, first antifuse element layer 12a may have a thickness between about 25 angstroms and about 45 angstroms, more generally between about 20 angstroms and about 50 angstroms, although other thicknesses may be used. In some embodiments, second antifuse element layer 12b may have a thickness between about 5 angstroms and about 15 angstroms, more generally between about 2 angstroms and about 20 angstroms, although other thicknesses may be used.

For example, first antifuse element layer 12a may be HfOₓ, ZrOₓ, LaₓO_{y}, TaₓO_{y}, SrTiOₓ, or other similar dielectric material, second antifuse element layer 12b may be TiOₓ, SiO₂, Al₂O₃, Si₃N₄, or other similar dielectric material. Other similar dielectric materials may be used.

First and second antifuse elements 12a and 12b may be formed over n+ polysilicon region 14c using any suitable formation process, such as ALD, PVD, RTO, HDP-CVD, CVD, SPA, or other similar processes. Persons of ordinary skill in the art will understand that other processes may be used to form first and second antifuse elements 12a and 12b. For low current operation and good data retention, first and second antifuse elements 12a and 12b preferably are formed as an amorphous structure.

Top electrode 26 is formed above first and second antifuse elements 12a and 12b, and is formed of highly doped semiconductor material. Without wanting to be bound by any particular theory, it is believed that top electrode 26 may act as in-situ current limiter, and may limit current through MIM stack 30b1 during programming events.

In the embodiment of FIG. 3E, top electrode 26 is p+ Si having a doping concentration between about 1×10²⁰ cm⁻³ and about 1×10²² cm⁻³. Persons of ordinary skill in the art will understand that other doping types and doping concentrations may be used.

In some embodiments, p+ Si top electrode 26 may have a thickness between about 20 angstroms and about 150 angstroms, more generally between about 10 angstroms and about 250 angstroms, although other thicknesses may be used. p+ Si top electrode 26 may be formed by CVD, LPCVD, PECVD, sputter deposition, laser ablation deposition, epitaxy growth deposition, or other similar processes. p+ Si top electrode 26 may be formed using the example processing parameters of Table 2, above. As described above, second conductor 18 is formed above MIM stack 30b1.

Referring now to FIG. 3F, an alternative example memory cell 10b2 is described. Example memory cell 10b2 is similar to example memory cell 10b1 of FIG. 3E, except that diode 14 is inverted, with n+ Si layer 14a on the bottom of diode 14, and p+ Si layer 14c on the top of diode 14, and memory cell 10b2 includes MIM stack 30b2, which shares p+ polysilicon region 14c with diode 14. In this regard, p+ polysilicon region 14c functions not only as part of diode 14, but also as a bottom electrode of MIM stack 30b2.

n+ Si top electrode 26 may have a doping concentration between about 1×10²⁰ cm⁻³ and about 1×10²² cm⁻³, a thickness between about 20 angstroms and about 150 angstroms, more generally between about 10 angstroms and about 250 angstroms, and may be formed by CVD, LPCVD, PECVD, sputter deposition, laser ablation deposition, epitaxy growth deposition, or other similar processes. Persons of ordinary skill in the art will understand that other doping types and doping concentrations, thicknesses, and processing techniques may be used. n+ Si top electrode 26 may be formed using the example processing parameters of Table 1, above.

FIG. 3G shows an example memory cell 10b3 which is similar to example memory cell 10b2 of FIG. 3F, except that memory cell 10b3 includes a MIM stack 30b3, with p+ Si top electrode 26.

p+ Si top electrode 26 may have a doping concentration between about 1×10²⁰ cm⁻³ and about 1×10²² cm⁻³, a thickness between about 20 angstroms and about 150 angstroms, more generally between about 10 angstroms and about 250 angstroms, and may be formed by CVD, LPCVD, PECVD, sputter deposition, laser ablation deposition, epitaxy growth deposition, or other similar processes. Persons of ordinary skill in the art will understand that other doping types and doping concentrations, thicknesses, and processing techniques may be used. p+ Si top electrode 26 may be formed using the example processing parameters of Table 2, above.

FIG. 3H shows an example memory cell 10b4 which is similar to example memory cell 10b1 of FIG. 3E, except that memory cell 10b4 includes a MIM stack 30b4, with n+ Si top electrode 26.

n+ Si top electrode 26 may have a doping concentration between about 1×10²⁰ cm⁻³ and about 1×10²² cm⁻³, a thickness between about 20 angstroms and about 150 angstroms, more generally between about 10 angstroms and about 250 angstroms, and may be formed by CVD, LPCVD, PECVD, sputter deposition, laser ablation deposition, epitaxy growth deposition, or other similar processes. Persons of ordinary skill in the art will understand that other doping types and doping concentrations, thicknesses, and processing techniques may be used. n+ Si top electrode 26 may be formed using the example processing parameters of Table 1, above.

FIGS. 3A-3H illustrate just a few of the various combinations of antifuse structures, diode structures and MIM stacks that may be used in accordance with this invention.

### Example Fabrication Processes for Memory Cells

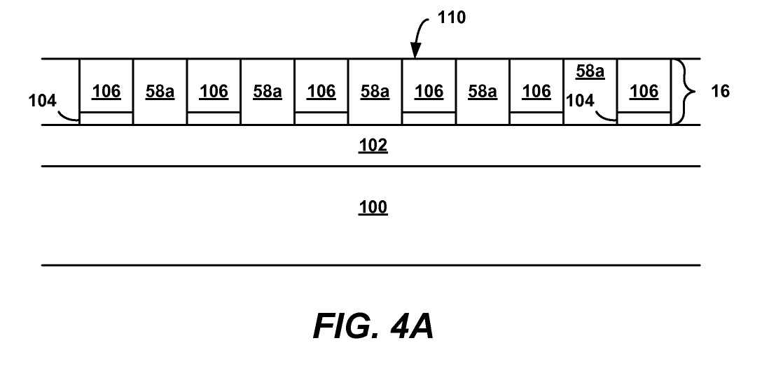

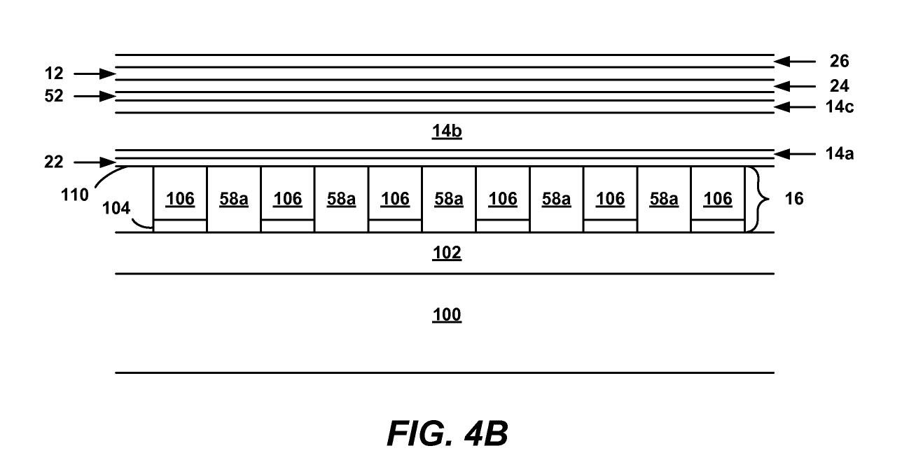

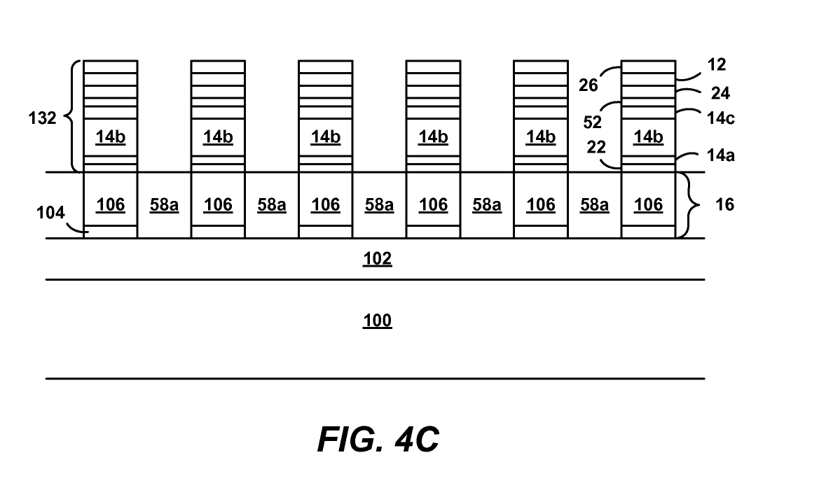

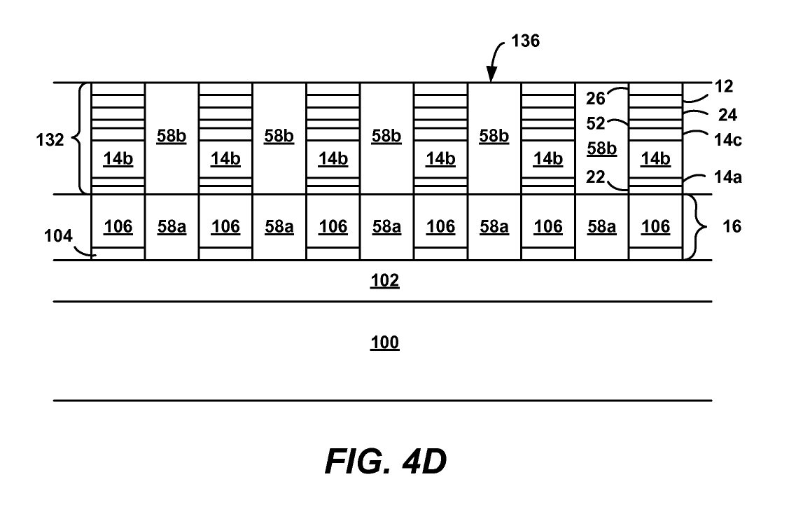

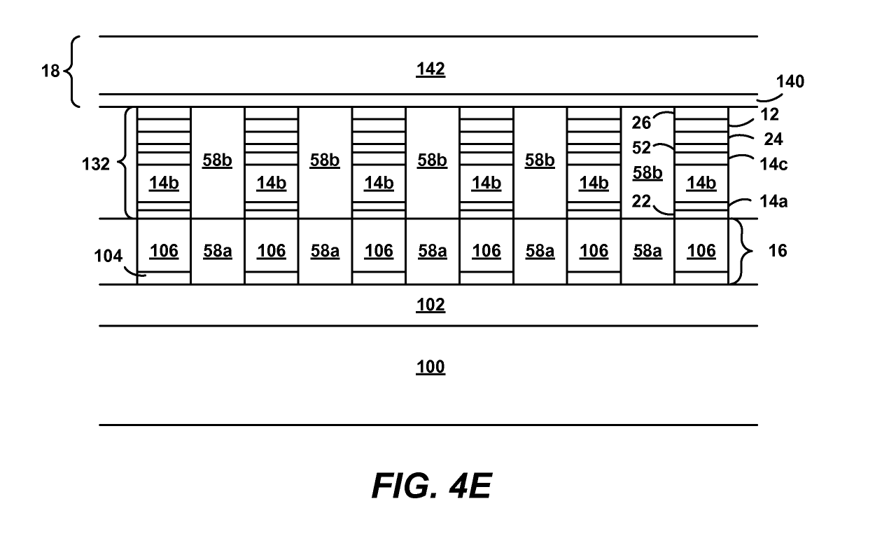

Referring now to FIGS. 4A-4E, an example method of forming a memory level in accordance with this invention is described. In particular, FIGS. 4A-4E illustrate an example method of forming a memory level including memory cells 10a1 of FIG. 3A. As will be described below, the first memory level includes a plurality of memory cells that each include a MIM stack coupled to a diode, with the MIM stack including a top electrode fabricated from highly doped semiconductor material. Additional memory levels may be fabricated above the first memory level (as described previously with reference to FIGS. 2D-2E).

With reference to FIG. 4A, substrate 100 is shown as having already undergone several processing steps. Substrate 100 may be any suitable substrate such as a silicon, germanium, silicon-germanium, undoped, doped, bulk, silicon-on-insulator (“SOI”) or other substrate with or without additional circuitry. For example, substrate 100 may include one or more n-well or p-well regions (not shown).

Isolation layer 102 is formed above substrate 100. In some embodiments, isolation layer 102 may be a layer of silicon dioxide, silicon nitride, silicon oxynitride or any other suitable insulating layer.

Following formation of isolation layer 102, an adhesion layer 104 is formed over isolation layer 102 (e.g., by PVD or another method). For example, adhesion layer 104 may be between about 20 and about 500 angstroms, and preferably about 100 angstroms, of titanium nitride or another suitable adhesion layer such as tantalum nitride, tungsten nitride, tungsten, molybdenum, combinations of one or more adhesion layers, or the like. Other adhesion layer materials and/or thicknesses may be employed. In some embodiments, adhesion layer 104 may be optional.

After formation of adhesion layer 104, a conductive layer 106 is deposited over adhesion layer 104. Conductive layer 106 may include any suitable conductive material such as tungsten or another appropriate metal, heavily doped semiconductor material, a conductive silicide, a conductive silicide-germanide, a conductive germanide, or the like deposited by any suitable method (e.g., CVD, PVD, etc.). In at least one embodiment, conductive layer 106 may comprise between about 200 and about 2500 angstroms of tungsten. Other conductive layer materials and/or thicknesses may be used.

Following formation of conductive layer 106, adhesion layer 104 and conductive layer 106 are patterned and etched. For example, adhesion layer 104 and conductive layer 106 may be patterned and etched using conventional lithography techniques, with a soft or hard mask, and wet or dry etch processing. In at least one embodiment, adhesion layer 104 and conductive layer 106 are patterned and etched to form substantially parallel, substantially co-planar first conductors 16. Example widths for first conductors 16 and/or spacings between first conductors 16 range between about 200 and about 2500 angstroms, although other conductor widths and/or spacings may be used.

After first conductors 16 have been formed, a dielectric material layer 58a is formed over substrate 100 to fill the voids between first conductors 16. For example, approximately 3000-7000 angstroms of silicon dioxide may be deposited on the substrate 100 and planarized using chemical mechanical polishing or an etchback process to form a planar surface 110. Planar surface 110 includes exposed top surfaces of first conductors 16 separated by dielectric material (as shown). Other dielectric materials such as silicon nitride, silicon oxynitride, low K dielectrics, etc., and/or other dielectric material layer thicknesses may be used. Example low K dielectrics include carbon doped oxides, silicon carbon layers, or the like.

In other embodiments of the invention, first conductors 16 may be formed using a damascene process in which dielectric material layer 58a is formed, patterned and etched to create openings or voids for first conductors 16. The openings or voids then may be filled with adhesion layer 104 and conductive layer 106 (and/or a conductive seed, conductive fill and/or barrier layer if needed). Adhesion layer 104 and conductive layer 106 then may be planarized to form planar surface 110. In such an embodiment, adhesion layer 104 will line the bottom and sidewalls of each opening or void.

Following planarization, the diode structures of each memory cell are formed. With reference to FIG. 4B, a barrier layer 22 is formed over planarized top surface 110 of substrate 100. In some embodiments, barrier layer 22 may be between about 20 and about 500 angstroms, and preferably about 100 angstroms, of titanium nitride or another suitable barrier layer such as tantalum nitride, tungsten nitride, tungsten, molybdenum, combinations of one or more barrier layers, barrier layers in combination with other layers such as titanium/titanium nitride, tantalum/tantalum nitride or tungsten/tungsten nitride stacks, or the like. Other barrier layer materials and/or thicknesses may be employed.

After deposition of barrier layer 22, deposition of the semiconductor material used to form the diode of each memory cell begins (e.g., diode 14 in FIGS. 1 and 3A). Each diode may be a vertical p-n or p-i-n diode as previously described. In some embodiments, each diode is formed from a polycrystalline semiconductor material such as polysilicon, a polycrystalline silicon-germanium alloy, polygermanium or any other suitable material. For convenience, formation of a polysilicon, upward-pointing diode is described herein. It will be understood that other materials and/or diode configurations may be used.

With reference to FIG. 4B, following formation of barrier layer 22, a heavily doped p+ silicon layer 14a is deposited on barrier layer 22. In some embodiments, p+ silicon layer 14a is in an amorphous state as deposited. In other embodiments, p+ silicon layer 14a is in a polycrystalline state as deposited. CVD or another suitable process may be employed to deposit p+ silicon layer 14a.

P-type silicon may be either deposited and doped by ion implantation or may be doped in situ during deposition to form a p+ silicon layer 14a. For example, an intrinsic silicon layer may be deposited, and then a blanket p+ implant may be employed to implant boron a predetermined depth within the intrinsic silicon layer. Example implantable molecular ions include BF₂, BF₃, B and the like. In some embodiments, an implant dose of about 1-5×10¹⁵ ions/cm² may be employed. Other implant species and/or doses may be used. Further, in some embodiments, a diffusion process may be employed. In at least one embodiment, the resultant p+ silicon layer 14a has a thickness of about 50-700 angstroms, although other p+ silicon layer sizes may be used.

After deposition of p+ silicon layer 14a, a lightly doped, intrinsic and/or unintentionally doped silicon layer 14b may be formed over p+ silicon layer 14a. In some embodiments, intrinsic silicon layer 14b may be in an amorphous state as deposited. In other embodiments, intrinsic silicon layer 14b may be in a polycrystalline state as deposited. CVD or another suitable deposition method may be employed to deposit intrinsic silicon layer 14b. In at least one embodiment, intrinsic silicon layer 14b may be about 300 to about 4800 angstroms, preferably about 2500 angstroms, in thickness. Other intrinsic layer thicknesses may be used.

A thin (e.g., a few hundred angstroms or less) germanium and/or silicon-germanium alloy layer (not shown) may be formed on p+ silicon layer 14a prior to depositing intrinsic silicon layer 14b to prevent and/or reduce dopant migration from p+ silicon layer 14a into intrinsic silicon layer 14b (as described in the '331 application).

A heavily doped n+ silicon layer 14c is deposited on intrinsic silicon layer 14b. In some embodiments, n+ silicon layer 14c is in an amorphous state as deposited. In other embodiments, n+ silicon layer 14c is in a polycrystalline state as deposited. CVD or another suitable process may be employed to deposit n+ silicon layer 14c. In at least one embodiment, n+ silicon layer 14c may be formed, for example, from about 50 to about 1000 angstroms, preferably about 100 angstroms, of phosphorus or arsenic doped silicon having a doping concentration of about 10²¹ cm⁻³. Other layer thicknesses, doping types and/or doping concentrations may be used. N+ silicon layer 14c may be doped in situ, for example, by flowing a donor gas during deposition. Other doping methods may be used (e.g., implantation).

A silicide-forming metal layer 52 is deposited over n+ silicon layer 14c. Example silicide-forming metals include sputter or otherwise deposited titanium or cobalt. In some embodiments, silicide-forming metal layer 52 has a thickness of about 10 to about 200 angstroms, preferably about 20 to about 50 angstroms and more preferably about 20 angstroms. Other silicide-forming metal layer materials and/or thicknesses may be used. A nitride layer (not shown) may be formed at the top of silicide-forming metal layer 52.

Following formation of silicide-forming metal layer 52, an RTA step may be performed at about 600° C. for about one minute to form silicide layer 50 (FIG. 3A), consuming all or a portion of the silicide-forming metal layer 52. Following the RTA step, any residual nitride layer from silicide-forming metal layer 52 may be stripped using a wet chemistry, as described above. Other annealing conditions may be used.

Following the RTA step and the nitride strip step, bottom electrode 24 is formed above silicide layer 50. Bottom electrode 24 may be between about 20 angstroms and about 150 angstroms, more generally between about 10 angstroms and about 250 angstroms of n+ Si having a doping concentration between about 1×10²⁰ cm⁻³ and about 1×10²² cm⁻³. n+ Si bottom may be formed by CVD, LPCVD, PECVD, sputter deposition, laser ablation deposition, epitaxy growth deposition, or other similar processes. Persons of ordinary skill in the art will understand that other doping types and doping concentrations, thicknesses, and processing techniques may be used. n+ Si bottom electrode 24 may be formed using the example processing parameters of Table 1, above.

First and second antifuse elements 12a and 12b are formed above n+ Si bottom electrode 24. In some embodiments, first antifuse element layer 12a may have a thickness between about 25 angstroms and about 45 angstroms, more generally between about 20 angstroms and about 50 angstroms, although other thicknesses may be used. In some embodiments, second antifuse element layer 12b may have a thickness between about 5 angstroms and about 15 angstroms, more generally between about 2 angstroms and about 20 angstroms, although other thicknesses may be used.

For example, first antifuse element layer 12a may be HfOₓ, ZrOₓ, LaₓO_{y}, TaₓO_{y}, SrTiOₓ, or other similar dielectric material, second antifuse element layer 12b may be TiOₓ, SiO₂, Al₂O₃, Si₃N₄, or other similar dielectric material. Other similar dielectric materials may be used.

First and second antifuse elements 12a and 12b may be formed over n+ Si bottom electrode 24 using any suitable formation process, such as ALD, PVD, RTO, HDP-CVD, CVD, SPA, or other similar processes. Persons of ordinary skill in the art will understand that other processes may be used to form first and second antifuse elements 12a and 12b. For low current operation and good data retention, first and second antifuse elements 12a and 12b preferably are each formed as an amorphous structure.

Top electrode 26 is formed above first and second antifuse elements 12a and 12b. Top electrode 26 may be between about 20 angstroms and about 150 angstroms, more generally between about 10 angstroms and about 250 angstroms of p+ Si having a doping concentration between about 1×10²⁰ cm⁻³ and about 1×10²² cm⁻³. p+ Si bottom electrode 24 may be formed by CVD, LPCVD, PECVD, sputter deposition, laser ablation deposition, epitaxy growth deposition, or other similar processes. Persons of ordinary skill in the art will understand that other doping types and doping concentrations, thicknesses, and processing techniques may be used. p+ Si bottom electrode 24 may be formed using the example processing parameters of Table 2, above.

As shown in FIG. 4C, top electrode 26, first and second antifuse elements 12a and 12b, bottom electrode 24, silicide-forming metal layer 52, diode layers 14a-14c, and barrier layer 22 are patterned and etched to form pillars 132. Pillars 132 may be formed above corresponding first conductors 16 and have substantially the same width as first conductors 16, for example, although other widths may be used. Some misalignment may be tolerated. The memory cell layers may be patterned and etched in a single pattern/etch procedure or using separate pattern/etch steps. In at least one embodiment, top electrode 26, first and second antifuse elements 12a and 12b and bottom electrode 24 are etched together to form MIM stack 30a1 (FIG. 3A).

For example, photoresist may be deposited, patterned using standard photolithography techniques, layers 22, 14a-14c, 52, 24, 12a, 12b, and 26 may be etched, and then the photoresist may be removed. Alternatively, a hard mask of some other material, for example silicon dioxide, may be formed on top of top electrode 26, with bottom antireflective coating (“BARC”) on top, then patterned and etched. Similarly, dielectric antireflective coating (“DARC”) may be used as a hard mask. In some embodiments, one or more additional metal layers may be formed above first and second antifuse elements 12a and 12b and diode 14 and used as a metal hard mask that remains part of pillars 132.

Pillars 132 may be formed using any suitable masking and etching process. For example, layers 22, 14a-14c, 52, 24, 12a, 12b, and 26 may be patterned with about 1 to about 1.5 micron, more preferably about 1.2 to about 1.4 micron, of photoresist (“PR”) using standard photolithographic techniques. Thinner PR layers may be used with smaller critical dimensions and technology nodes. In some embodiments, an oxide hard mask may be used below the PR layer to improve pattern transfer and protect underlying layers during etching.

In some embodiments, after etching, pillars 132 may be cleaned using a dilute hydrofluoric/sulfuric acid clean. Such cleaning may be performed in any suitable cleaning tool, such as a Raider tool, available from Semitool of Kalispell, Mont. Example post-etch cleaning may include using ultra-dilute sulfuric acid (e.g., about 1.5-1.8 wt %) for about 60 seconds and/or ultra-dilute hydrofluoric (“HF”) acid (e.g., about 0.4-0.6 wt %) for 60 seconds. Megasonics may or may not be used. Other clean chemistries, times and/or techniques may be employed.

A dielectric material layer 58b is deposited over pillars 132 to fill the voids between pillars 132. For example, approximately 2000-7000 angstroms of silicon dioxide may be deposited and planarized using chemical mechanical polishing or an etchback process to form a planar surface 136, resulting in the structure illustrated in FIG. 4D. Planar surface 136 includes exposed top surfaces of pillars 132 separated by dielectric material 58b (as shown). Other dielectric materials such as silicon nitride, silicon oxynitride, low K dielectrics, etc., and/or other dielectric material layer thicknesses may be used.

With reference to FIG. 4E, second conductors 18 may be formed above pillars 132. For example, in some embodiments, one or more barrier layers and/or adhesion layers 140 may be deposited over pillars 132 prior to deposition of a conductive layer 142 used to form second conductors 18. In addition, as described above in connection with FIG. 3A, planar surface 136 may be cleaned prior to forming adhesion layers 140 and conductive layer 142.

Adhesion layer 140 may include titanium nitride or another suitable layer such as tantalum nitride, tungsten nitride, tungsten, molybdenum, combinations of one or more layers, or any other suitable material(s). For example, a tungsten nitride layer 140 between about 50 angstroms and about 200 angstroms may be deposited on planar surface 136. Conductive layer 142 may be formed from any suitable conductive material such as tungsten, another suitable metal, heavily doped semiconductor material, a conductive silicide, a conductive silicide-germanide, a conductive germanide, or the like deposited by PVD or any other any suitable method (e.g., CVD, etc.). Other conductive layer materials may be used.

Conductive layer 142 and adhesion layer 140 may be patterned and etched to form second conductors 18. In at least one embodiment, second conductors 18 are substantially parallel, substantially coplanar conductors that extend in a different direction than first conductors 16.

In other embodiments of the invention, second conductors 18 may be formed using a damascene process in which a dielectric material layer is formed, patterned and etched to create openings or voids for conductors 18. The openings or voids may be filled with adhesion layer 140 and conductive layer 142 (and/or a conductive seed, conductive fill and/or barrier layer if needed). Adhesion layer 140 and conductive layer 142 then may be planarized to form a planar surface.

Following formation of second conductors 18, the resultant structure may be annealed to crystallize the deposited semiconductor material of diodes 14 (and/or to form silicide regions by reaction of the silicide-forming metal layer 52 with n+ region 14c). In alternative embodiments, the arrangements of the doped silicon layers is reversed, so silicide-forming metal layer 52 is in contact with p+ region 14a. The lattice spacing of titanium silicide and cobalt silicide are close to that of silicon, and it appears that such silicide layers may serve as “crystallization templates” or “seeds” for adjacent deposited silicon as the deposited silicon crystallizes. Lower resistivity diode material thereby is provided. Similar results may be achieved for silicon-germanium alloy and/or germanium diodes.

Thus in at least one embodiment, a crystallization anneal may be performed for about 10 seconds to about 2 minutes in nitrogen at a temperature of about 600 to 800° C., and more preferably between about 650 and 750° C. Other annealing times, temperatures and/or environments may be used.

Additional memory levels may be similarly formed above the memory level of FIGS. 4A-4E. Persons of ordinary skill in the art will understand that alternative memory cells in accordance with this invention may be fabricated with other suitable techniques.

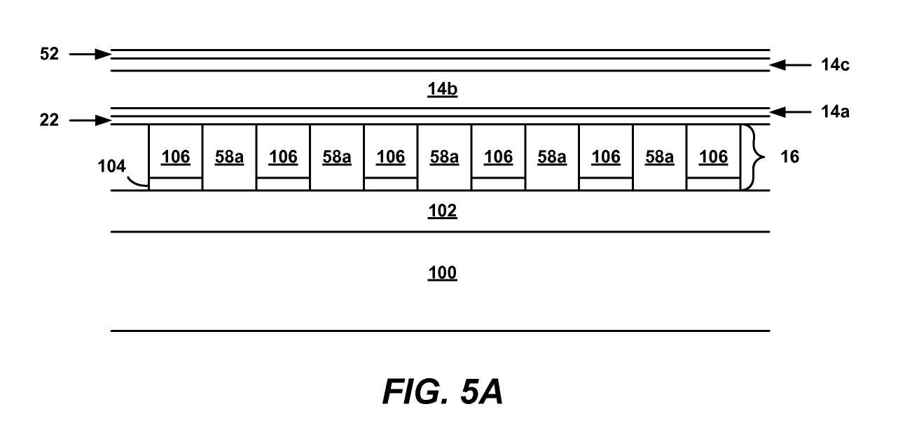

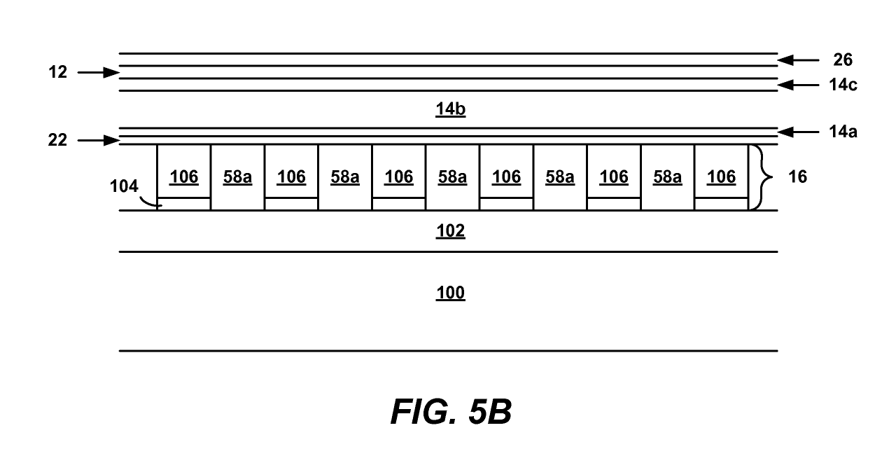

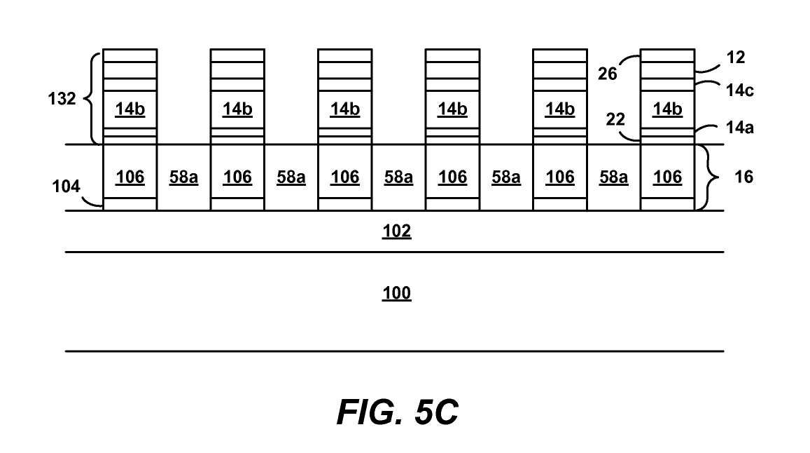

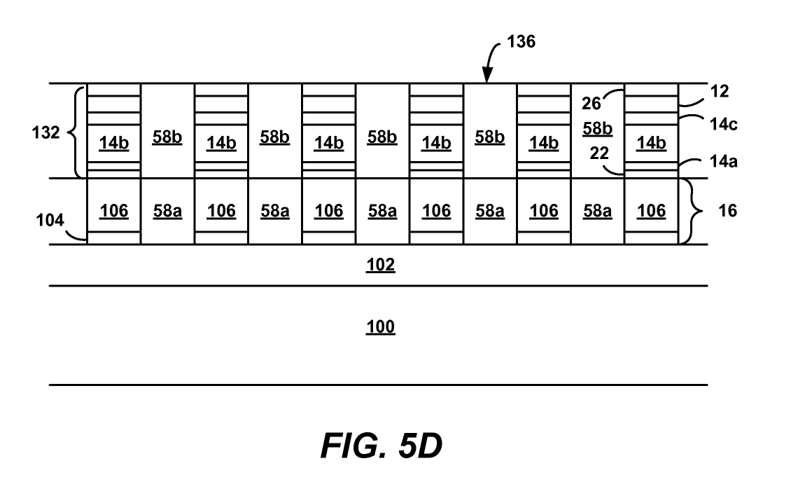

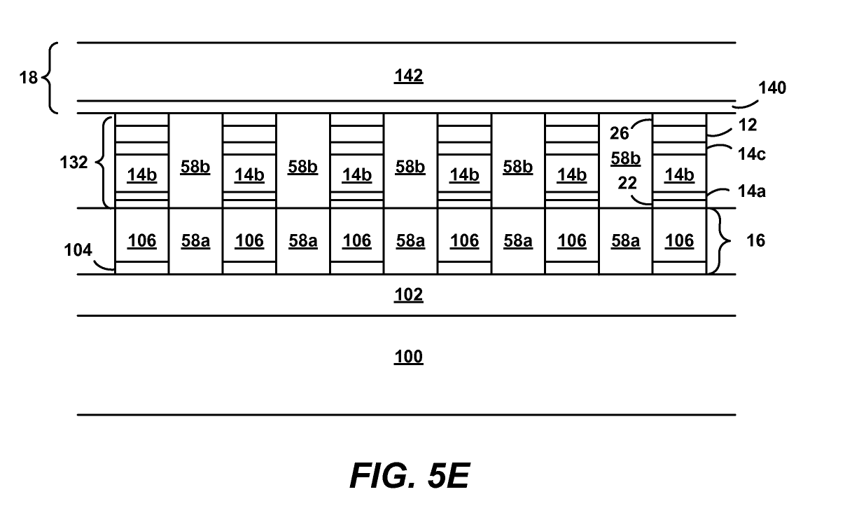

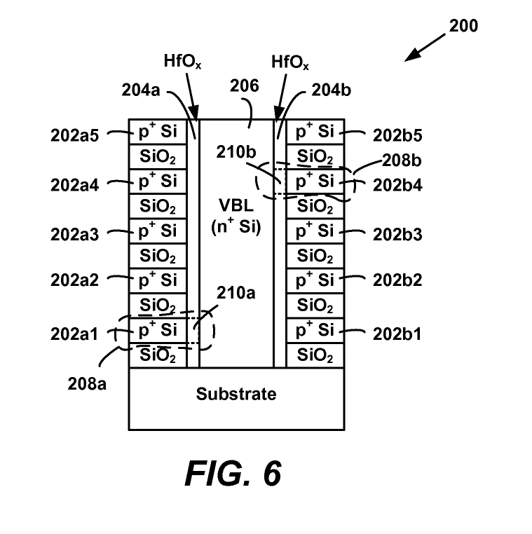

Referring now to FIGS. 5A-5E, another example method of forming a memory level in accordance with this invention is described. In particular, FIGS. 5A-5E illustrate an example method of forming a memory level including memory cells 10b1 of FIG. 3E. As will be described below, the first memory level includes a plurality of memory cells that each include a MIM stack coupled to a diode, with the MIM stack sharing a highly doped semiconductor layer with the diode, with the highly doped semiconductor layer serving as both the bottom electrode of the MIM stack, and the top portion of the diode. Additional memory levels may be fabricated above the first memory level (as described previously with reference to FIGS. 2D-2E).

With reference to FIG. 5A, substrate 100 is shown as having already undergone several processing steps, including formation of substantially parallel, substantially co-planar first conductors 16, barrier layer 22, heavily doped p+ silicon layer 14a, lightly doped, intrinsic and/or unintentionally doped silicon layer 14b, heavily doped n+ silicon layer 14c and silicide-forming metal layer 52, such as described above in connection with FIGS. 4A-4B.

In addition, as described above, following formation of silicide-forming metal layer 52, an RTA step may be performed to form silicide layer 50 (FIG. 3E), and then the silicide-forming metal layer (and any nitride layer) are removed. For example, if silicide-forming metal layer 52 is a Ti/TiN layer, a wet chemistry (e.g., ammonium, peroxide, water in a 1:1:1 ratio) may be used to strip the residual Ti/TiN, leaving heavily doped n+ silicon layer 14c exposed. A CMP step may be desired to smooth out the surface of n+ poly-silicon region 14c after wet chemical removal of nitride layer.

First and second antifuse elements 12a and 12b are formed above heavily doped n+ silicon layer 14c, and top electrode 26 is formed above first and second antifuse elements 12a and 12b, such as described above in connection with FIG. 4B, resulting in the structure shown in FIG. 5B.

As shown in FIG. 5C, top electrode 26, first and second antifuse elements 12a and 12b, diode layers 14a-14c, and barrier layer 22 are patterned and etched to form pillars 132. Pillars 132 may be formed above corresponding first conductors 16 and have substantially the same width as first conductors 16, for example, although other widths may be used. Some misalignment may be tolerated. The memory cell layers may be patterned and etched in a single pattern/etch procedure or using separate pattern/etch steps, such as described above in connection with FIG. 4C. Top electrode 26, first and second antifuse elements 12a and 12b and heavily doped n+ silicon layer 14c form MIM stack 30b1 (FIG. 3E).

A dielectric material layer 58b is deposited over pillars 132 to fill the voids between pillars 132, and then planarized to form a planar surface 136, such as described above in connection with FIG. 4D, resulting in the structure shown in FIG. 5D. Planar surface 136 includes exposed top surfaces of pillars 132 separated by dielectric material 58b (as shown).

With reference to FIG. 5E, second conductors 18 may be formed above pillars 132, such as described above in connection with FIG. 4E. Following formation of second conductors 18, the resultant structure may be annealed to crystallize the deposited semiconductor material of diodes 14 (and/or to form silicide regions by reaction of the silicide-forming metal layer 52 with n+ region 14c), such as described above.

Additional memory levels may be similarly formed above the memory level of FIGS. 5A-5E. Persons of ordinary skill in the art will understand that alternative memory cells in accordance with this invention may be fabricated with other suitable techniques.

### Example Vertical Bitline Memory Structure

Referring now to FIG. 6, another example three-dimensional memory array in accordance with this invention is described. In particular, FIG. 6 illustrates a three-dimensional memory array 200 that includes first word line conductors 202a1, 202a2, 202a3, 202a4 and 202a5, second word line conductors 202b1, 202b2, 202b3, 202b4 and 202b5, first antifuse element 204a, second antifuse element 204b, and a vertically oriented bit line 206. Memory array 200 is a type of memory array sometimes called a vertical bitline memory array, such as the vertical bitline memory arrays described in Samachisa U.S. Pat. No. 7,983,065, which is incorporated by reference herein in its entirety for all purposes.

First word line conductors 202a1, 202a2, 202a3, 202a4 and 202a5, and second word line conductors 202b1, 202b2, 202b3, 202b4 and 202b5 are formed of a highly-doped semiconductor material, such as p+ Si, p+ SiGe, n+ Si, n+ SiGe, or other similar highly doped semiconductor material or combination of semiconductor materials. Dielectric material layers, such as SiO₂ layers, or other similar dielectric material layers, separate adjacent First word line conductors 202a1, 202a2, 202a3, 202a4 and 202a5, and second word line conductors 202b1, 202b2, 202b3, 202b4 and 202b5

For example, first word line conductors 202a1, 202a2, 202a3, 202a4 and 202a5, and second word line conductors 202b1, 202b2, 202b3, 202b4 and 202b5 each may be n+ Si having a doping concentration between about 1×10²⁰ cm⁻³ and about 1×10²² cm⁻³, each having a thickness between about 20 angstroms and about 150 angstroms, more generally between about 10 angstroms and about 250 angstroms, and each may be formed by CVD, LPCVD, PECVD, sputter deposition, laser ablation deposition, epitaxy growth deposition, or other similar processes. Persons of ordinary skill in the art will understand that other doping types, doping concentrations and thicknesses may be used.

In addition, although five first word line conductors 202a1, 202a2, 202a3, 202a4 and 202a5, and five second word line conductors 202b1, 202b2, 202b3, 202b4 and 202b5 are shown in FIG. 6, persons of ordinary skill in the art will understand that more or less than five first word line conductors and second word line conductors may be used.

First antifuse element 204a is formed between first word line conductors 202a1, 202a2, 202a3, 202a4 and 202a5 and vertically oriented bit line 206, and second antifuse element 204b is formed between second word line conductors 202b1, 202b2, 202b3, 202b4 and 202b5 and vertically oriented bit line 206. In some embodiments, first antifuse element 204a and second antifuse element 204b each may have a thickness between about 25 angstroms and about 45 angstroms, more generally between about 20 angstroms and about 50 angstroms, although other thicknesses may be used.

First antifuse element layer 204a and second antifuse element 204b each may be HfOₓ, ZrOₓ, LaₓO_{y}, TaₓO_{y}, SrTiOₓ, or other similar dielectric material. First and second antifuse elements 204a and 204b may be formed using any suitable formation process, such as ALD, PVD, RTO, HDP-CVD, CVD, SPA, or other similar processes. Persons of ordinary skill in the art will understand that other processes may be used to form first and second antifuse elements 204a and 204b.

Vertically oriented bit line 206 is formed of a highly-doped semiconductor material, such as p+ Si, p+ SiGe, n+ Si, n+ SiGe, or other similar highly doped semiconductor material or combination of semiconductor materials. For example, vertically oriented bit line 206 may be p+ Si having a doping concentration between about 1×10²⁰ cm⁻³ and about 1×10²² cm⁻³, having a thickness between about 800 angstroms and about 1200 angstroms, more generally between about 600 angstroms and about 1400 angstroms, and may be formed by CVD, LPCVD, PECVD, sputter deposition, laser ablation deposition, epitaxy growth deposition, or other similar processes. Persons of ordinary skill in the art will understand that other doping types, doping concentrations and thicknesses may be used.

Memory array 200 includes multiple memory cells 208, with each memory cell 208 including one of the first word line conductors 202a1, 202a2, 202a3, 202a4 and 202a5, or second word line conductors 202b1, 202b2, 202b3, 202b4 and 202b5, a portion of first antifuse element layer 204a or second antifuse element 204b, and vertically oriented bit line 206. For example, memory cell 208a includes first word line conductor 202a1, a portion 210a of first antifuse element layer 204a adjacent first word line conductor 202a1, and vertically oriented bit line 206. Memory cell 208b includes second word line conductor 202b4, a portion 210b of second antifuse element layer 204b adjacent second word line conductor 202b4, and vertically oriented bit line 206.

Memory array 200 does not include Ti/TiN-containing layers, such as adhesion layers. Without wanting to be bound by any particular theory, it is believed that by eliminating Ti/TiN adhesion layers, such three-dimensional arrays of memory cells substantially eliminates the risk of TiN migration.

The foregoing description discloses example embodiments of the invention. Modifications of the above disclosed apparatus and methods which fall within the scope of the invention will be readily apparent to those of ordinary skill in the art.

Accordingly, although the present invention has been disclosed in connection with example embodiments thereof, it should be understood that other embodiments may fall within the spirit and scope of the invention, as defined by the following claims.

1. A memory cell comprising:
a steering element;
a metal-insulator-metal (“MIM”) stack coupled in series with the steering element, wherein the MIM stack comprises a resistance switching element and a top electrode disposed on the resistance switching element, and the top electrode comprises a highly doped semiconductor material; and
a conductor disposed above the MIM stack,
wherein the memory cell does not include a metal layer disposed between the MIM stack and the conductor.

2. The memory cell of claim 1, wherein the steering element comprises a diode.

3. The memory cell of claim 1, wherein the steering element comprises a vertically oriented diode.

4. The memory cell of claim 1, wherein the steering element comprises a p-n or p-i-n diode.

5. The memory cell of claim 1, wherein the MIM stack is disposed above or below the steering element.

6. The memory cell of claim 1, wherein the resistance-switching material comprises a dielectric material.

7. The memory cell of claim 6, wherein the dielectric material comprises one or more of HfOₓ, ZrOₓ, LaₓO_{y}, TaₓO_{y}, SrTiOₓ, TiOₓ, SiO₂, Al₂O₃, and Si₃N₄.

8. The memory cell of claim 6, wherein the dielectric material comprises a plurality of dielectric material layers.

9. The memory cell of claim 6, wherein dielectric material comprises a first dielectric material layer comprising one or more of one or more of HfOₓ, ZrOₓ, LaₓO_{y}, TaₓO_{y}, SrTiOₓ, and a second dielectric material layer comprising one or more of TiOₓ, SiO₂, Al₂O₃, or Si₃N₄.

10. The memory cell of claim 1, wherein the top electrode comprises one of p+ silicon, p+ silicon-germanium, n+ silicon, and n+ silicon-germanium.

11. The memory cell of claim 1, wherein the MIM stack comprises a portion of the steering element.

12. The memory cell of claim 11, wherein
the steering element comprises a diode.

13. The memory cell of claim 1, wherein the MIM stack further comprises a bottom electrode disposed below the resistance-switching element, wherein the bottom electrode comprises a highly doped semiconductor material.

14. The memory cell of claim 13, wherein
the bottom electrode comprises one of p+ silicon, p+ silicon-germanium, n+ silicon, and n+ silicon-germanium.

15. A monolithic three-dimensional memory array comprising:
a first memory level monolithically formed above a substrate, the first memory level comprising a plurality of memory cells, wherein each memory cell comprises:
a steering element;
a metal-insulator-metal (“MIM”) stack coupled in series with the steering element, wherein the MIM stack comprises a resistance switching element and a top electrode disposed on the resistance switching element, and the top electrode comprises a highly doped semiconductor material; and
a conductor disposed above the MIM stack,
wherein the memory cell does not include a metal layer disposed between the MIM stack and the conductor; and
a second memory level monolithically formed above the first memory level.

16. The monolithic three-dimensional memory array of claim 15, wherein the steering element comprises a diode.

17. The monolithic three-dimensional memory array of claim 15, wherein the steering element comprises a vertically oriented diode.

18. The monolithic three-dimensional memory array of claim 15, wherein the steering element comprises a p-n or p-i-n diode.

19. The monolithic three-dimensional memory array of claim 15, wherein each MIM stack is disposed above or below the steering element.

20. The monolithic three-dimensional memory array of claim 15, wherein the resistance-switching material comprises a dielectric material.

21. The monolithic three-dimensional memory array of claim 20, wherein the dielectric material comprises one or more of HfOₓ, ZrOₓ, LaₓO_{y}, TaₓO_{y}, SrTiOₓ, TiOₓ, SiO₂, Al₂O₃, and Si₃N₄.

22. The monolithic three-dimensional memory array of claim 20, wherein the dielectric material comprises a plurality of dielectric material layers.

23. The monolithic three-dimensional memory array of claim 20, wherein dielectric material comprises a first dielectric material layer comprising one or more of one or more of HfOₓ, ZrOₓ, LaₓO_{y}, TaₓO_{y}, SrTiOₓ, and a second dielectric material layer comprising one or more of TiOₓ, SiO₂, Al₂O₃, or Si₃N₄.

24. The monolithic three-dimensional memory array of claim 15, wherein the top electrode comprises one of p+ silicon, p+ silicon-germanium, n+ silicon, and n+ silicon-germanium.

25. The monolithic three-dimensional memory array of claim 15, wherein the MIM stack comprises a portion of the steering element.

26. The monolithic three-dimensional memory array of claim 25, wherein the steering element comprises a diode.

27. The monolithic three-dimensional memory array of claim 15, wherein the MIM stack further comprises a bottom electrode disposed below the resistance-switching element, wherein the bottom electrode comprises a highly doped semiconductor material.

28. The monolithic three-dimensional memory array of claim 27, wherein the bottom electrode comprises one of p+ silicon, p+ silicon-germanium, n+ silicon, and n+ silicon-germanium.
